(19) United States
(12) Patent Application Publication
(10) Pub. No.: US 2025/0070054 A1
(43) Pub. Date: Feb. 27, 2025

(54) ONE-TIME-PROGRAMMABLE MEMORY DEVICES WITH HIGH SECURITY AND METHODS OF MANUFACTURING THEREOF

(71) Applicant: Taiwan Semiconductor Manufacturing Company, Ltd., Hsinchu (TW)

(72) Inventor: Meng-Sheng Chang, Hsinchu City (TW)

(73) Assignee: Taiwan Semiconductor Manufacturing Company, Ltd., Hsinchu (TW)

(21) Appl. No.: 18/405,951

(22) Filed: Jan. 5, 2024

Related U.S. Application Data
(60) Provisional application No. 63/520,815, filed on Aug. 21, 2023.
(60) Provisional application No. 63/607,709, filed on Dec. 8, 2023.

(51) Int. Cl. H01L 23/00; G11C 17/16; H10B 20/25

(52) U.S. Cl. CPC H01L 23/573; G11C 17/16; H10B 20/25

(57) ABSTRACT

A memory device includes a transistor formed along a frontside surface of a substrate. The memory device includes a first fuse resistor formed in a first metallization layer that is vertically disposed with respect to the frontside surface. The memory device includes a second fuse resistor formed in a second metallization layer that is vertically disposed with respect to the frontside surface, the first metallization layer being different from the second metallization layer. The second fuse resistor and the first fuse resistor are each coupled to the transistor.

### CROSS-REFERENCE TO RELATED APPLICATION

This application claims priority to and the benefit of both U.S. Provisional Application No. 63/520,815, filed Aug. 21, 2023, and U.S. Provisional Application No. 63/607,709, filed Dec. 8, 2023, both of which are incorporated herein by reference in their entireties for all purposes.

### BACKGROUND

In general, there are two main types of data storage elements. The first type is a volatile memory device, in which information stored in a particular storage element is lost the moment the power is removed from the memory device. The second type is a non-volatile memory device, in which the information is preserved even after the power is removed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an example memory device including a memory array, in accordance with some embodiments.

FIG. 2 illustrates a schematic diagram of an efuse memory cell the memory array of FIG. 1, in accordance with some embodiments.

FIG. 3 illustrates another schematic diagram of an efuse memory cell the memory array of FIG. 1, in accordance with some embodiments.

FIG. 4 illustrates yet another schematic diagram of an efuse memory cell the memory array of FIG. 1, in accordance with some embodiments.

FIG. 5 illustrates an example layout of an efuse memory cell of the memory array of FIG. 1, in accordance with some embodiments.

FIGS. 6, 7, 8, 9, and 10 illustrate cross-sectional views of a semiconductor device formed based on the layout of FIG. 5, in accordance with some embodiments.

FIG. 11 illustrates a hybrid cross-sectional view of a semiconductor device formed based on the layout of FIG. 5, in accordance with some embodiments.

FIG. 12 illustrates another example layout of an efuse memory cell of the memory array of FIG. 1, in accordance with some embodiments.

FIG. 13 illustrates a hybrid cross-sectional view of a semiconductor device formed based on the layout of FIG. 12, in accordance with some embodiments.

FIG. 14 illustrates another example layout of an efuse memory cell of the memory array of FIG. 1, in accordance with some embodiments.

FIG. 15 illustrates a hybrid cross-sectional view of a semiconductor device formed based on the layout of FIG. 14, in accordance with some embodiments.

FIG. 16 illustrates a hybrid cross-sectional view of a semiconductor device including an efuse memory cell, in accordance with some embodiments.

FIG. 17 illustrates a hybrid cross-sectional view of a semiconductor device including an efuse memory cell, in accordance with some embodiments.

FIG. 18 illustrates a hybrid cross-sectional view of a semiconductor device including an efuse memory cell, in accordance with some embodiments.

FIG. 19 illustrates a hybrid cross-sectional view of a semiconductor device including an efuse memory cell, in accordance with some embodiments.

FIG. 20 illustrates a hybrid cross-sectional view of a semiconductor device including an efuse memory cell, in accordance with some embodiments.

FIG. 21 illustrates a hybrid cross-sectional view of a semiconductor device including an efuse memory cell, in accordance with some embodiments.

FIG. 22 illustrates an example flow chart of a method for fabricating an efuse memory cell, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A one-time-programmable (OTP) memory device is one of various types of the non-volatile memory device. Example implementations of the OTP memory device include metal fuses, etc. The metal fuse utilizes a metal resistor serving as a programming element of the corresponding OTP memory device. Such a metal fuse is sometimes referred to as an efuse memory device, in which the metal resistor can typically be programmed (e.g., once). The programming process typically involves burning or blowing the metal resistor, causing it to transition from a short circuit (state) to an open circuit (state). The efuse memory device is commonly utilized in integrated circuits for adjusting the circuitry after fabrication of an integrated circuit. For example, the efuse memory device is used for providing repair information that controls the usage of redundant cells in replacing defective cells of a memory array. Another use is for tuning analog circuitry by trimming a capacitive or resistive value of an analog circuit or enabling and disabling portions of the system. In yet another example, a recent trend is that an integrated circuit (or a chip) may include a plural number of efuse memory cells with respective programmed states that can collectively function as a key of the integrated circuit for encryption or decryption purposes.

In the existing technologies, respective metal resistors of different efuse memory cells of an OTP memory device are typically formed in a common one of metallization layers disposed over a semiconductor substrate. This can lead to the key stored across the efuse memory cells being easily decrypted. For example, by reverse-engineering an integrated circuit, respectively different locations of blown (open circuit) and intact (short circuit) fuse resistors can be identified such that the key stored by the corresponding efuse memory cells will be easily cracked.

In this regard, the present disclosure provides various embodiments of a one-time-programmable (OTP) memory device that includes a number of efuse memory cells, each of which includes a plural number of programming elements (e.g., fuse or metal resistors) electrically coupled to a transistor. Such a transistor is generally gated by a word line (WL) signal to control access of the corresponding efuse memory cell (which is sometimes referred to as a WL transistor or access transistor). In various embodiments, the WL transistor is formed along the major (e.g., frontside) surface of a substrate, while the fuse resistors are formed in or between different metallization layers vertically arranged with respect to the frontside surface. For example, a first fuse resistor may be formed (as first metal tracks) in one of a plural number of frontside metallization layers that are disposed over a frontside of the substrate, and a second fuse resistor may be formed (as second metal tracks) in one of a plural number of backside metallization layers disposed over a backside of the substrate. In another example, a first fuse resistor may be formed (as first metal tracks) in a first one of a plural number of frontside metallization layers, and a second fuse resistor may be formed (as second metal tracks) in a second one of the frontside metallization layers. In yet another example, a first fuse resistor may be formed (as first metal tracks) in a first one of a plural number of frontside metallization layers, a second fuse resistor may be formed (as second metal tracks) in a second one of the frontside metallization layers, and a third fuse resistor may be formed (as one or more via structures) vertically between the first and second metallization layers.

By spreading the different programming elements (fuse resistors) of each efuse memory cell across respective positions (e.g., respective metallization layers), a key for which the efuse memory cells are configured can become significantly uncrackable. This is because the different fuse resistors of each efuse memory cell are randomly programmed, e.g., due to process variation. As such, even if all the positions of the blown (open circuit) and intact (short circuit) fuse resistors have been identified, it is nearly impossible to identify which efuse memory cell has been programmed. For example, each efuse memory cell can have a plural number of fuse resistors spread across respective positions within a chip, and which of the blown fuse resistors belongs to the corresponding efuse memory cell is challenging to be identified. Thus, the currently disclosed OTP memory device can provide a greatly enhanced level of security.

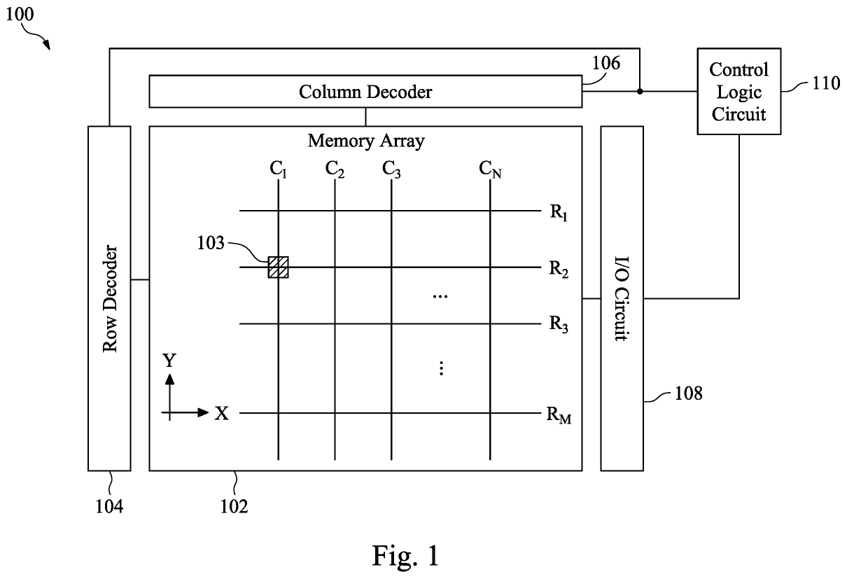

FIG. 1 illustrates a block diagram of a memory device 100, in accordance with various embodiments. In the illustrated embodiment of FIG. 1, the memory device 100 includes a memory array 102, a row decoder 104, a column decoder 106, an input/output (I/O) circuit 108, and a control logic circuit 110. Despite not being shown in FIG. 1, all of the components of the memory device 100 may be coupled to each other and to the control logic circuit 110. Although, in the illustrated embodiment of FIG. 1, each component is shown as a separate block for the purpose of clear illustration, in some other embodiments, some or all of the components shown in FIG. 1 may be integrated together. For example, the memory array 102 may include an embedded I/O circuit (e.g., 108).

The memory array 102 is a hardware component that stores data. In various embodiments, the memory array 102 is embodied as a semiconductor memory device. The memory array 102 includes a plurality of memory cells (or otherwise storage units) 103. The memory array 102 includes a number of rows R₁, R₂, R₃ . . . R_{M}, each extending in a first direction (e.g., the X-direction) and a number of columns C₁, C₂, C₃ . . . C_{N}, each extending in a second direction (e.g., the Y-direction). Each of the rows and columns may include one or more conductive (e.g., metal) structures functioning as access lines. Each memory cell 103 is arranged in the intersection of a corresponding row and a corresponding column, and can be operated according to voltages or currents through the respective conductive structures of the column and row. For example, each of the rows may include one or more corresponding word lines (WLs), and each of the columns may include one or more corresponding bit line (BLs).

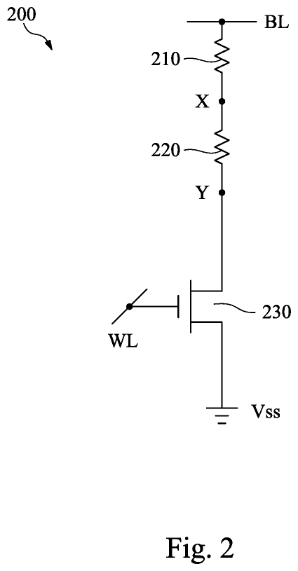

In some embodiments, each memory cell 103 is embodied as an efuse memory cell that may include a plural number of fuse resistors and a WL transistor. In various embodiments, each of the fuse resistors is coupled to the WL transistor, and the WL transistor and fuse resistors are coupled between a corresponding of the BLs and a source line which is generally tied to ground (VSS). For example, the fuse resistors are coupled to each other in series, and one of the fuse resistors has a terminal electrically connected to a first source/drain terminal of the WL transistor. Further, another one of the fuse resistors has a terminal electrically connected to the corresponding BL. In another example, the fuse resistors are coupled to each other in parallel, and the fuse resistors each have a first terminal electrically connected to the first source/drain of the WL transistor. Further, the fuse resistors each have a second terminal electrically connected to the corresponding BL. In either of the examples, a gate terminal of the WL transistor is connected to the corresponding WL, and a second source/drain terminal of the WL transistor is connected to the source line. Details of various implementations of the efuse memory cell will be discussed in further detail with respect to FIGS. 2, 3, and 4, respectively.

In some other embodiments, each of the memory cells 103 may be implemented as any of various other non-volatile memory cells. For example, the memory cell 103 may include a resistive random access memory (RRAM) cell, a magnetoresistive random access memory (MRAM) cell, a phase-change random access memory (PCRAM) cell, an anti-fuse, etc., while remaining within the scope of the present disclosure.

The row decoder 104 is a hardware component that can receive a row address of the memory array 102 and assert a conductive structure (e.g., the WL) at that row address. The column decoder 106 is a hardware component that can receive a column address of the memory array 102 and assert a conductive structure (e.g., the BL) at that column address. The I/O circuit 108 is a hardware component that can access (e.g., read, program) each of the memory cells 103 asserted through the row decoder 104 and column decoder 106. The control logic circuit 110 is a hardware component that can control the coupled components (e.g., 102 through 108).

FIGS. 2, 3, and 4 respectively illustrate example configurations 200, 300, and 400 of the efuse memory cell 103, in accordance with various embodiments. Hereinafter, the configurations in FIGS. 2, 3, and 4 are referred to as “efuse memory cell 200,” “efuse memory cell 300,” and “efuse memory cell 400,” respectively. In various embodiments, each of the efuse memory cells 200 to 400 has a multiple number of fuse resistors, causing the disclosed efuse memory cell to present a logic state with a randomly programmed fuse resistor. Further, the multiple fuse resistors are physically formed in respectively different vertical positions with respect to a substrate, which makes a position of the programmed fuse resistor difficult to be identified.

Referring first to FIG. 2, the efuse memory cell 200 consists of a first fuse resistor 210, a second fuse resistor 220, and a WL transistor 230 serially connected to one another between a BL and ground (VSS), with the WL transistor 230 gated through a WL. For example, the first fuse resistor 210 and the second fuse resistor 220 each have a first terminal and a second terminal, and the WL transistor 230 has a first source/drain terminal and a second source/drain terminal. The first terminal of the first fuse resistor 210 is connected to the BL, the second terminal of the first fuse resistor 210 is connected to the first terminal of the second fuse resistor 220 at node “X,” the second terminal of the second fuse resistor 220 is connected to the first source/drain terminal of the WL transistor 230 at node “Y,” and the second source/drain terminal of the WL transistor 230 is connected to ground.

The WL transistor 230 may be formed along the major (e.g., frontside) surface of a semiconductor substrate, which is sometimes referred to as part of front-end-of-line (FEOL) processing/network. Over the frontside surface, a number of first (or frontside) metallization layers, each of which includes a number of interconnect (e.g., metal) structures/tracks, can be formed, which are sometimes referred to as part of back-end-of-line (BEOL) processing/network. Such frontside metallization layers are sometimes referred to as M0 layer, M1 layer, M2 layer, and so on, and accordingly the frontside metal tracks included in the corresponding metallization layer (e.g., MX layer) are sometimes referred to as MX tracks. Over a backside surface of the substrate, a number of second (or backside) metallization layers, each of which includes a number of interconnect (e.g., metal) structures/tracks, can be formed. Such backside metallization layers are sometimes referred to as BM0 layer, BM1 layer, BM2 layer, and so on. Such backside metallization layers are sometimes referred to as BM0 layer, BM1 layer, BM2 layer, and so on, and accordingly the backside metal tracks included in the corresponding metallization layer (e.g., BMX layer) are sometimes referred to as BMX tracks.

In some embodiments, the first fuse resistor 210 can be formed as a number of backside metal tracks, and the second fuse resistor 220 can be formed as a number of frontside metal tracks. In some other embodiments, the first fuse resistor 210 can be formed as a number of frontside metal tracks in a first frontside metallization layer, and the second fuse resistor 220 can be formed as a number of frontside metal tracks in a second, different frontside metallization layer. Stated another way, the metal tracks operatively serving as the first fuse resistor 210, the metal tracks operatively serving as the second fuse resistor 220, and the WL transistor 230 are vertically spaced from one another, in various embodiments of the present disclosure.

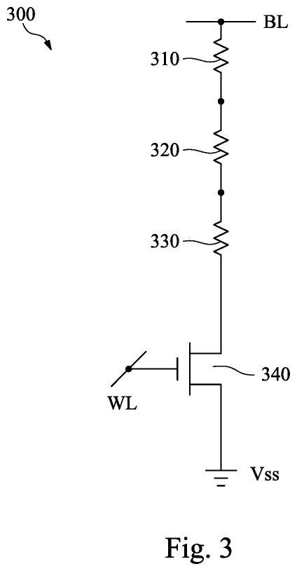

Referring next to FIG. 3, the efuse memory cell 300 consists of a first fuse resistor 310, a second fuse resistor 320, a third fuse resistor 330, and a WL transistor 340 serially connected to one another between a BL and ground (VSS), with the WL transistor 340 gated through a WL. For example, the first fuse resistor 310, the second fuse resistor 320, and the third fuse resistor 330 each have a first terminal and a second terminal, and the WL transistor 340 has a first source/drain terminal and a second source/drain terminal. The first terminal of the first fuse resistor 310 is connected to the BL, the second terminal of the first fuse resistor 310 is connected to the first terminal of the second fuse resistor 320, the second terminal of the second fuse resistor 320 is connected to the first terminal of the third fuse resistor 330, the second terminal of the third fuse resistor 330 is connected to the first source/drain terminal of the WL transistor 340, and the second source/drain terminal of the WL transistor 340 is connected to ground.

Similarly, the WL transistor 340 may be formed along the frontside surface of a semiconductor substrate. In some embodiments, the first fuse resistor 310 can be formed as a number of backside metal tracks, and the third fuse resistor 330 can be formed as a number of frontside metal tracks, while the second fuse resistor 320, coupled between the first and third fuse resistors 310 and 330, can be formed as a backside via structure vertically between the metal tracks operatively forming the first fuse resistor 310 and the metal tracks operatively forming the third fuse resistor 330. In some other embodiments, the first fuse resistor 310 can be formed as a number of frontside metal tracks in a first frontside metallization layer, and the third fuse resistor 320 can be formed as a number of frontside metal tracks in a second, different frontside metallization layer, while the second fuse resistor 320, coupled between the first and third fuse resistors 310 and 330, can be formed as a frontside via structure vertically between the metal tracks operatively forming the first fuse resistor 310 and the metal tracks operatively forming the third fuse resistor 330. Stated another way, the metal tracks operatively serving as the first fuse resistor 310, the metal tracks operatively serving as the third fuse resistor 330, the via structure(s) operatively serving as the second fuse resistor 320, and the WL transistor 340 are vertically spaced from one another, in various embodiments of the present disclosure.

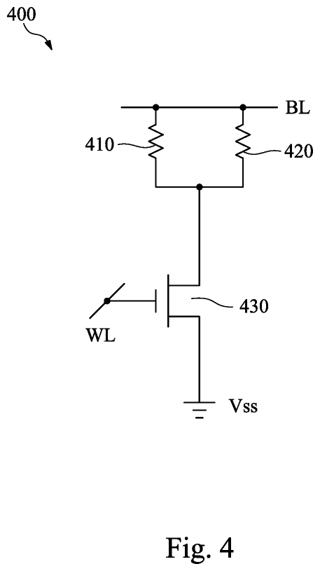

Referring then to FIG. 4, the efuse memory cell 400 consists of a first fuse resistor 410, a second fuse resistor 420, and a WL transistor 430. Each of the first fuse resistor 410 and the second fuse resistor 420 is serially connected to the WL transistor 430 between a BL and ground (VSS), with the WL transistor 430 gated through a WL. Stated another way, the first fuse resistor 410 and the second fuse resistor 420 may be connected to each in parallel, and each of the first fuse resistor 410 and the second fuse resistor 420 is further connected to the WL transistor 430 in series. For example, the first fuse resistor 410 and the second fuse resistor 420 each have a first terminal and a second terminal, and the WL transistor 430 has a first source/drain terminal and a second source/drain terminal. The first terminals of the first fuse resistor 410 and the second fuse resistor 420 are commonly connected to the BL, the second terminals of the first fuse resistor 410 and the second fuse resistor 420 are commonly connected to the first source/drain terminal of the WL transistor 430, and the second source/drain terminal of the WL transistor 430 is connected to ground.

Similarly, the WL transistor 430 may be formed along the frontside surface of a semiconductor substrate. In some embodiments, the first fuse resistor 410 can be formed as a number of backside metal tracks, and the second fuse resistor 420 can be formed as a number of frontside metal tracks. In some other embodiments, the first fuse resistor 410 can be formed as a number of frontside metal tracks in a first frontside metallization layer, and the second fuse resistor 420 can be formed as a number of frontside metal tracks in a second, different frontside metallization layer. Stated another way, the metal tracks operatively serving as the first fuse resistor 410, the metal tracks operatively serving as the second fuse resistor 420, and the WL transistor 430 are vertically spaced from one another, in various embodiments of the present disclosure.

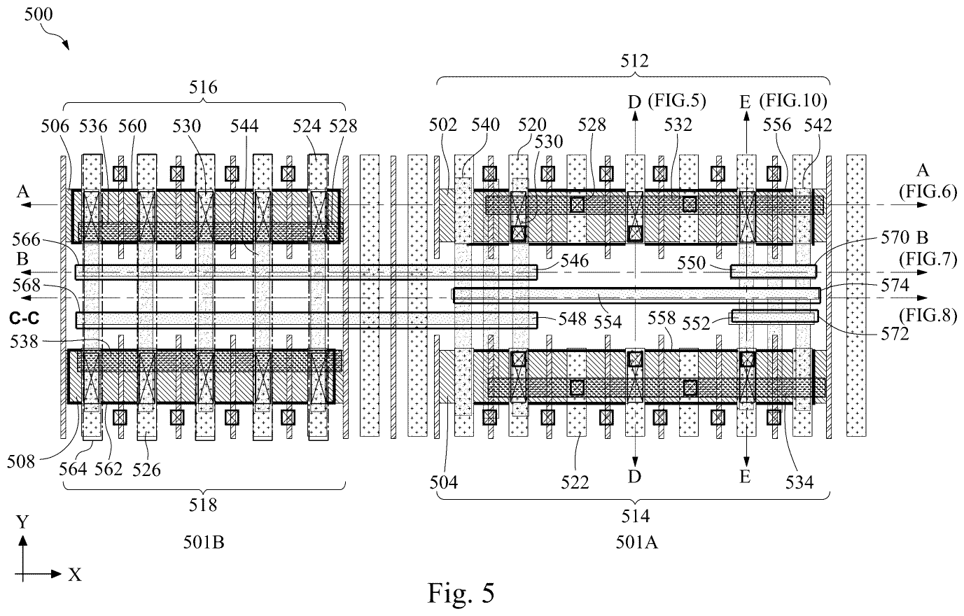

Referring to FIG. 5, an example layout 500 that can be utilized to form the efuse memory cell 200 (FIG. 2) is illustrated, in accordance with some embodiments. As discussed above, the efuse memory cell 200 includes a WL transistor, and first and second fuse resistors coupled to one another in series. The WL transistor may be constructed by a number (e.g., 100) of sub-transistors that are coupled to one another in parallel and formed along the frontside surface of a substrate, while the first and second fuse resistors are each constructed by a respective number of metal tracks vertically spaced from the frontside surface. In some embodiments, the layout 500 may be configured to form the metal tracks of the first fuse resistor on a backside of the substrate, and the metal tracks of the second fuse resistor on a frontside of the substrate.

As shown, the layout 500 includes patterns 502, 504, 506, and 508 that are each configured to form an oxide diffusion region (hereinafter “oxide diffusion region 502,” “oxide diffusion region 504,” “oxide diffusion region 506,” and “oxide diffusion region 508,” “respectively); and a number of patterns 512, a number of patterns 514, a number of patterns 516, and a number of patterns 518 that are each configured to form a gate structure (hereinafter “gate structure 512,” “gate structure 514,” “gate structure 516,” and “gate structure 518,” respectively). In some embodiments, the oxide diffusion regions 502 to 508 may each extend along a first lateral direction (e.g., the X-direction), while the gate structures 512 to 518 may each extend along a second, different lateral direction (e.g., the Y-direction). It should be understood that the layout 500 can include any number of each of the oxide diffusion regions and gate structures, while remaining within the scope of present disclosure.

In some embodiments, the layout 500 can be utilized to form at least one efuse memory cell 200 over a substrate. Further, the oxide diffusion regions 502-504, together with the gate structures 512-514, may be disposed in a first area of the substrate, 501A, while the oxide diffusion regions 506-508, together with the gate structures 516-518, may be disposed in a second area of the substrate, 501B. Such first and second areas may be spaced apart from each other along the X-direction with one or more dummy patterns (structures), as shown in FIG. 5.

Each of the gate structures 512 to 518 traverses a corresponding one of the oxide diffusion regions 502 to 508 to form a sub-transistor. In some embodiments, each of the oxide diffusion regions 502 to 508 is formed of a stack structure protruding from a major (e.g., frontside) surface of the substrate. The stack includes a number of semiconductor nanostructures (e.g., nanosheets) extending along the X-direction and vertically separated from each other. Portions of the semiconductor structures in the stack that are overlaid by the gate structure remain, while other portions are replaced with a number of epitaxial structures. The remaining portions of the semiconductor structures can be configured as the channel of a corresponding transistor (or sub-transistor), the epitaxial structures coupled to both sides (or ends) of the remaining portions of the semiconductor structures can be configured as source/drain structures (or terminals) of the transistor (or sub-transistor), and a portion of the gate structure that overlays (e.g., straddles) the remaining portions of the semiconductor structures can be configured as a gate structures (or terminal) of the transistor (or sub-transistor).

For example in FIG. 5, the portion of the oxide diffusion region 502 that is overlaid by each of the gate structures 512 may include a number of nanostructures vertically separated from each other, which can function as the channel of a first active sub-transistor. The portions of the oxide diffusion region 502 that are disposed on opposite sides of each of the gate structures 512 are replaced with epitaxial structures. Such epitaxial structures can function as source/drain terminals of the first active sub-transistor. The gate structure 512 can function as a gate terminal of the first active sub-transistor. Similarly, a second active sub-transistor can be formed by the oxide diffusion region 504 and each of the gate structures 514. Thus, it should be appreciated that the layout 500 (in the area 501A) can be used to fabricate a certain number of these active sub-transistors, which are coupled to each other in parallel to collectively function as the WL transistor 230 (FIG. 2).

For example, adjacent first active sub-transistors (formed by the oxide diffusion region 502 and the adjacent gate structures 512) have their source or drain terminals connected to each other by sharing a first common epitaxial structure, and adjacent first active sub-transistors (formed by the oxide diffusion region 504 and the adjacent gate structures 514) have their source or drain terminals connected to each other by sharing a second common epitaxial structure. Further, such first common epitaxial structures are each aligned with a corresponding one of the second common epitaxial structures along the Y-direction, allowing them to be connected to each other through one or more metal tracks which will be discussed below.

Further, the layout 500 (in the area 501B) can be used to fabricate a certain number of dummy sub-transistors. For example, a number of first dummy sub-transistors can be formed by the oxide diffusion region 506 and the gate structures 516, and a number of second dummy sub-transistors can be formed by the oxide diffusion region 508 and the gate structures 518. In some embodiments, each of the first and second dummy sub-transistors has its gate terminal, drain terminal, and source terminal connected to ground (VSS). As will be discussed below, the first and second dummy sub-transistors may be formed to allow or otherwise facilitate connection (e.g., backside via structures, VBs) between the frontside and the backside of the substrate.

The layout 500 further includes patterns 520, 522, 524, and 526 that are each configured to form a middle-end interconnection structure, sometime referred to as an MD (hereinafter “MD 520,” “MD 522,” “MD 524,” and “MD 526,” “respectively). The MDs 520 to 526 may each extend along the second lateral direction (e.g., the Y-direction) to traverse a corresponding one of the oxide diffusion regions 502 to 508, and may be interposed between adjacent gate structures. The MDs 520 to 526 are each configured to couple a corresponding source/drain terminal to an upper metal track (e.g., an M0 track) through a middle-end via structure, sometimes referred to as a VD, and/or to a lower metal track (e.g., a BM0 track) through a backside via structure, sometimes referred to as a VB. For example, the layout 500 includes a number of patterns 528 that are each configured to form a VD (hereinafter “VD 528”), and a number of patterns 530 that each configured to form a VB (hereinafter “VB 530”).

The layout 500 further includes patterns 532, 534, 536, 538, 540, 542, 544, 546, 548, 550, 552, 554, 556, 558, 560, 562, 564, 566, 568, 570, 572, and 574 that are each configured to form a metal structure/track in a corresponding metallization layer. In some embodiments, the metal tracks, formed by the patterns 532, 534, 536, and 538, are each an M0 track (hereinafter “M0 track 532,” “M0 track 534,” “M0 track 536,” and “M0 track 538,” respectively); the metal tracks, formed by the patterns 540, 542, and 544, are each an M1 track (hereinafter “M1 track 540,” “M1 track 542,” and “M1 track 544,” respectively); the metal tracks, formed by the patterns 546, 548, 550, 552, and 554, are each an M2 track (hereinafter “M2 track 546,” “M2 track 548,” “M2 track 550,” “M2 track 552,” and “M2 track 554,” respectively); the metal tracks, formed by the patterns 556, 558, 560, and 562, are each a BM0 track (hereinafter “BM0 track 556,” “BM0 track 558,” “BM0 track 560,” and “BM0 track 562,” respectively); the metal tracks, formed by the patterns 564, are each a BM1 track (hereinafter “BM1 track 564”); and the metal tracks, formed by the patterns 566, 568, 570, 572, and 574, are each a BM2 track (hereinafter “BM2 track 566,” “BM2 track 568,” “BM2 track 570,” “BM2 track 572,” and “BM2 track 574,” respectively).

In some embodiments, the M0 tracks 532-538, M1 tracks 540-544, and M2 tracks 546-554 are formed on the frontside of the substrate, while the BM0 tracks 556-562, BM1 tracks 564, and BM2 tracks 566-574 are formed on the backside of the substrate. The M0 tracks 532-534 can couple one source/drain terminal of the WL transistor 230 (FIG. 2) to a terminal of the second fuse resistor 220 (FIG. 2) that is formed by the M2 tracks 546-554 through at least the M1 tracks 542, and the other terminal of the second fuse resistor 220 can be coupled to one of the terminals of the first fuse resistor 210 (FIG. 2) that is formed by the BM2 tracks 566-574 through at least the M1 tracks 544, M0 tracks 536-538, MDs 524-526, VBs 530, BM0 tracks 560-562, and BM1 tracks 564.

The M0 track 532 can be coupled to a first one of the source/drain terminals of the WL transistor 230 (formed by the oxide diffusion region 502 and the gate structures 512) through the underlying MDs 520 and VDs 528. Specifically, the M0 track 532 may be coupled to every other one of the MDs 520 (or every other one of the epitaxial structures formed in the oxide diffusion region 502). Similarly, the M0 track 534 can be coupled to the first source/drain terminal of the WL transistor 230 (formed by the oxide diffusion region 504 and the gate structures 514) through the underlying MDs 522 and VDs 528. Specifically, the M0 track 534 may be coupled to every other one of the MDs 522 (or every other one of the epitaxial structures formed in the oxide diffusion region 504) that are aligned with the MDs 520 (connected to the M0 track 532) along the Y-direction, respectively. The M0 tracks 532 and 534 can each have its right-hand end coupled to the M1 tracks 542, and each of the M1 tracks 542 can be coupled to the M2 tracks 550-552 and a right-hand end of the M2 track 554.

As mentioned above, the M2 tracks 546-554 can collectively function as the second fuse resistor 220, and thus, such ends coupled to the M1 tracks 542 can function as the terminal of the second fuse resistor 220 connected to the first source/drain terminal of the WL transistor 230 (e.g., the node Y of FIG. 2). An opposite end of the M2 track 554 and the M2 tracks 546-548 (which function as the other terminal of the second fuse resistor 220) can be coupled to one of the terminals of the first fuse resistor 210 that is formed by the BM2 tracks 566-572 (e.g., the node X of FIG. 2), which will be discussed below.

The BM0 tracks 556 can be coupled to a second one of the source/drain terminals of the WL transistor 230 through a subset of the VBs 530. Specifically, the BM0 track 556 may be coupled to every other one of the epitaxial structures formed in the oxide diffusion region 502. Similarly, the BM0 track 558 can be coupled to the second source/drain terminal of the WL transistor 230 through another subset of the VBs 530. Specifically, the BM0 track 558 may be coupled to every other one of the epitaxial structures formed in the oxide diffusion region 504 that are aligned with the epitaxial structures formed in the oxide diffusion region 502 (connected to the BM0 track 556) along the Y-direction, respectively. In some embodiments, the BM0 tracks 556 and 558 can each be configured to carry a supply voltage, e.g., ground (VSS). Accordingly, the second source/drain terminal of the WL transistor 230 can be tied to ground.

The M2 tracks 546 and 548 can each extend away from the M2 tracks 550-552 along the X-direction to reach the area 501B, in some embodiments. As shown, along the Y-direction, the M2 tracks 546 and 548 each have a portion interposed between vertical projections of the oxide diffusion regions 506 and 508. These portions of the M2 tracks 546-548 can be coupled to each of the epitaxial structures formed in the oxide diffusion regions 506 and 508 (e.g., each source/drain terminal of the dummy sub-transistors) through at least the M1 tracks 544, M0 tracks 536-538, VDs 528, and MDs 524-526. These epitaxial structures can be further coupled to the BM0 tracks 560-562 through yet another subset of the VBs 530. The BM0 tracks 560-562 can be coupled to the BM1 tracks 564, which can be coupled to portions of the BM2 tracks 566-568 in the area 501B. Similar to the M2 tracks 546-548, each of the BM2 tracks 566-568 extends toward the BM2 tracks 570-572 to reach the area 501A.

As mentioned above, the M2 tracks 566-572 can collectively function as the first fuse resistor 210. Accordingly, a left-hand end of the BM2 track 574 and right-hand ends of the BM2 tracks 566-568 can function as the terminal of the first fuse resistor 210 connected to the second fuse resistor 220 (e.g., the node X of FIG. 2). An opposite end of the BM2 track 574 and the BM2 tracks 570-572 (which function as the other terminal of the first fuse resistor 210) can be coupled to a BL. In some embodiments, the BM2 tracks 570-572, similar to the M2 tracks 546-548, can each have a portion extending away from the BM2 tracks 566-568 along the X-direction to allow a connection to the BL. Although not expressly shown in FIG. 5, it should be understood that such extending portion of the M2 tracks 570-572 may be despised in another area of the substrate opposite the area 501A from the area 501B (along the X-direction). The BL may be formed as one or more metal tracks disposed on the frontside of the substate. The BL can be coupled to the source/drain terminal of an input/output transistor or peripheral transistor, which will be discussed below.

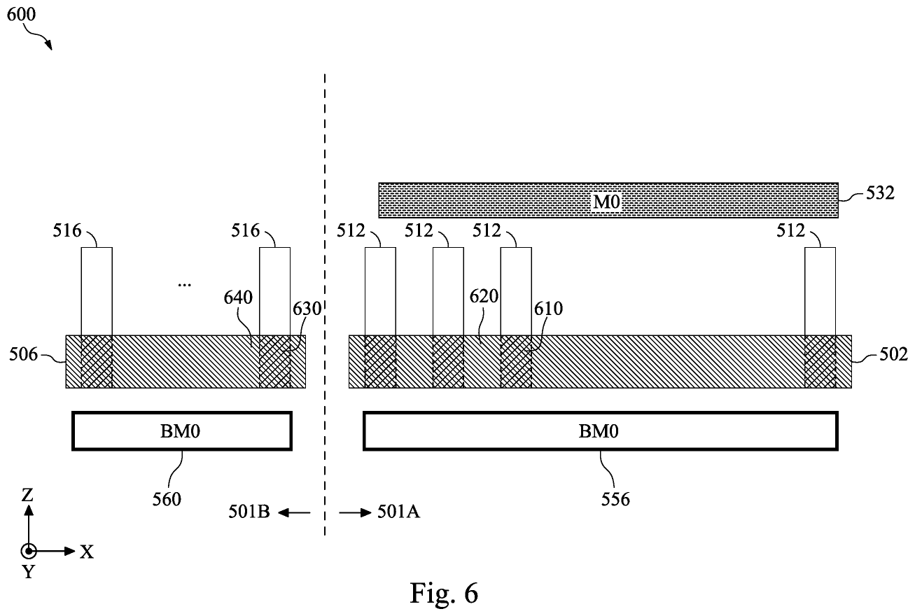

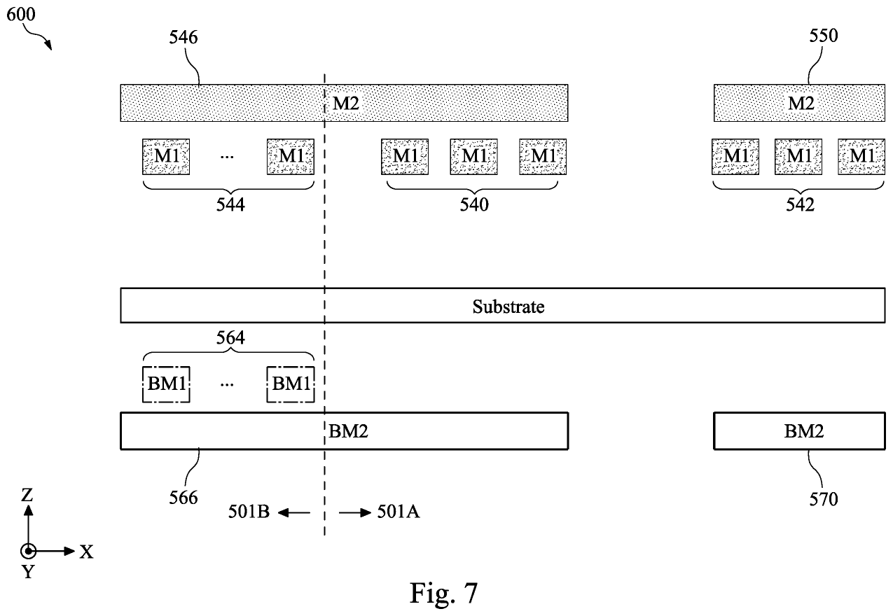

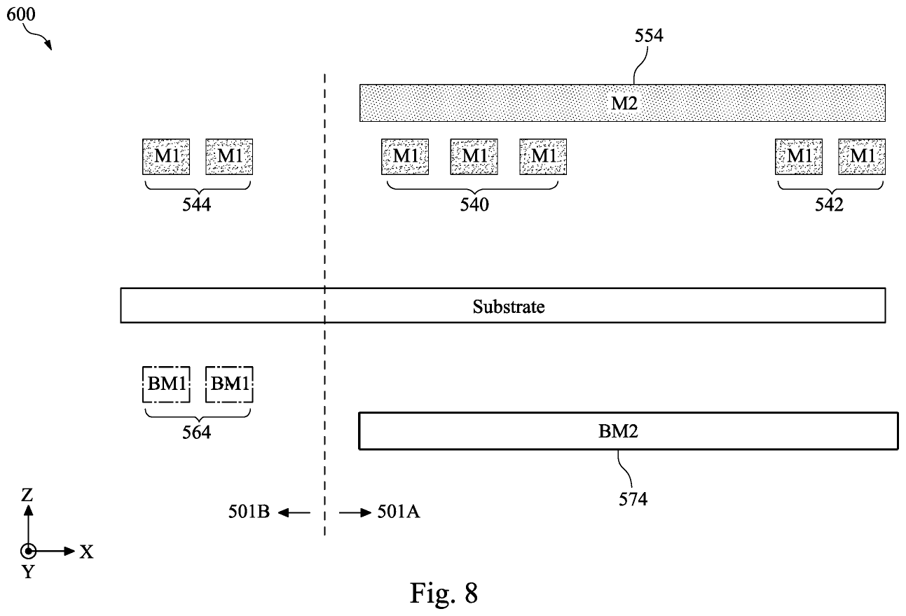

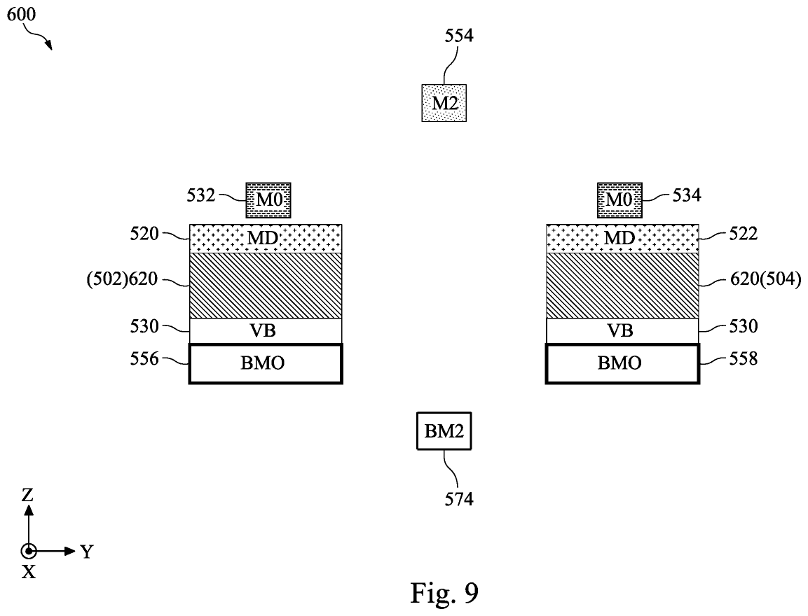

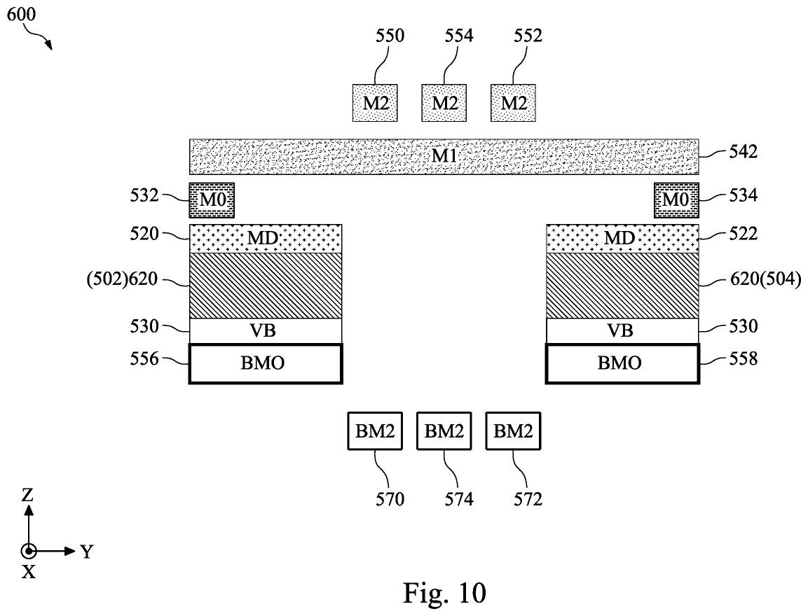

FIGS. 6, 7, 8, 9, and 10 illustrate cross-sectional views of a semiconductor device 600 that can be formed based on the layout 500 of FIG. 5, respectively, in accordance with some embodiments. As such, some of the reference numerals of FIG. 5 may be reused in the following discussion of FIGS. 6-10. For example, the cross-sectional view of FIG. 6 is cut along line A-A which extends through the oxide diffusion regions 502 and 506 and the M0 track 532 along the X-direction, as indicated in FIG. 5; the cross-sectional view of FIG. 7 is cut along line B-B which extends through the M2 tracks 546 and 550 and the BM2 tracks 566 and 570 along the X-direction, as indicated in FIG. 5; the cross-sectional view of FIG. 8 is cut along line C-C which extends through the M2 track 554 and the BM2 track 574 along the X-direction, as indicated in FIG. 5; the cross-sectional view of FIG. 9 is cut along line D-D which traverses the M2 track 554 and the BM2 track 574 along the Y-direction, as indicated in FIG. 5; and the cross-sectional view of FIG. 10 is cut along line E-E which traverses the M2 tracks 550-554 and the BM2 tracks 570-574 along the Y-direction, as indicated in FIG. 5. It should be understood that the cross-sectional views of FIGS. 6-10 are simplified for illustrative purposes, and thus, some of the components may be omitted.

In FIG. 6, along the oxide diffusion region 502 in the area 501A, a number of channels 610 and epitaxial structures 620 can be formed. Each of the channels 610 can be overlaid or wrapped by a corresponding one of the gate structures 512, and some of the epitaxial structures can be overlaid by a corresponding MD (not shown). Similarly, along the oxide diffusion region 506 in the area 501B, a number of channels 630 and epitaxial structures 640 can be formed. Each of the channels 630 can be overlaid or wrapped by a corresponding one of the gate structures 516, and some of the epitaxial structures can be overlaid by a corresponding MD (not shown). Over the frontside of the oxide diffusion region 502, the M0 track 532 is formed above the gate structures 512, and over the backside of the oxide diffusion region 502 (or the substrate in the area 501A), the BM0 track 556 is formed. Further, over the backside of the oxide diffusion region 506 (or the substate in the area 501B), the BM0 track 560 is formed.

In FIG. 7, over the frontside of the substrate, the M1 tracks 540-542 are formed in the area 501A (e.g., where the oxide diffusion regions 502-504 are formed) and the M1 tracks 544 are formed in the area 501B (e.g., where the oxide diffusion regions 506-508 are formed), with a portion of the M2 track 546 and the M2 track 550 being further formed over the M1 tracks 540-542, and with another portion of the M2 track 546 being further formed over the M1 tracks 544. Over the backside of the substrate, a portion of the BM2 track 566 and the BM2 track 570 are formed in the area 501A, and another portion of the BM2 track 566 is formed in the area 501B. In some embodiments, there may be no BM1 tracks interposed between the backside of the substrate and the upper metal tracks (e.g., BM2 tracks 566 and 570) in the area 501A, while the BM1 tracks 564 may be interposed between the backside of the substrate and the BM2 track 566 in the area 501B.

In FIG. 8, over the frontside of the substrate, the M1 tracks 540-542 are formed in the area 501A (e.g., where the oxide diffusion regions 502-504 are formed) and the M1 tracks 544 are formed in the area 501B (e.g., where the oxide diffusion regions 506-508 are formed), with the M2 track 554 being further formed over the M1 tracks 540-542. Over the backside of the substrate, the BM2 track 574 is formed in the area 501A. In some embodiments, there may be no BM1 tracks interposed between the backside of the substrate and the upper metal tracks (e.g., BM2 track 574) in the area 501A, while the BM1 tracks 564 may be interposed between the backside of the substrate and other BM2 tracks (or other upper metal tracks) in the area 501B.

In FIG. 9, the MDs 530 and 522 are connected to the frontside of the epitaxial structures 620 in the oxide diffusion regions 502 and 504, respectively. The M2 track 554 is further formed over the MDs 520-522, with the M0 tracks 532-534 interposed therebetween. In some embodiments, the M2 track 554 may be interposed between the oxide diffusion regions 502 and 504 along the Y-direction. On the backside, the BM0 tracks 556 and 558 are connected to the epitaxial structures 620 through a first one and a second one of the VBs 530, respectively. The BM2 track 574 is further formed over the BM0 tracks 556-558. In some embodiments, the BM2 track 574 may be interposed between the oxide diffusion regions 502 and 504 along the Y-direction, and more specifically, the BM2 track 574 can be vertically aligned with the M2 track 554. In some embodiments, the BM0 tracks 556-558 may be configured to carry a supply voltage (e.g., ground), which ties the second source/drain terminal of the WL transistor 230 to ground (as mentioned above).

In FIG. 10, the MDs 530 and 522 are connected to the frontside of the epitaxial structures 620 in the oxide diffusion regions 502 and 504, respectively. The M2 tracks 550 to 554 are each further formed over the MDs 520-522, with the M0 tracks 532-534 and the M1 track 542 interposed therebetween. In some embodiments, the M2 tracks 550-554 may be interposed between the oxide diffusion regions 502 and 504 along the Y-direction. On the backside, the BM0 tracks 556 and 558 are connected to the epitaxial structures 620 through a first one and a second one of the VBs 530, respectively. The BM2 track 570-574 are further formed over the BM0 tracks 556-558. In some embodiments, the BM2 tracks 570-574 may be interposed between the oxide diffusion regions 502 and 504 along the Y-direction, and more specifically, the BM2 tracks 570-574 can be vertically aligned with the M2 tracks 550-554, respectively.

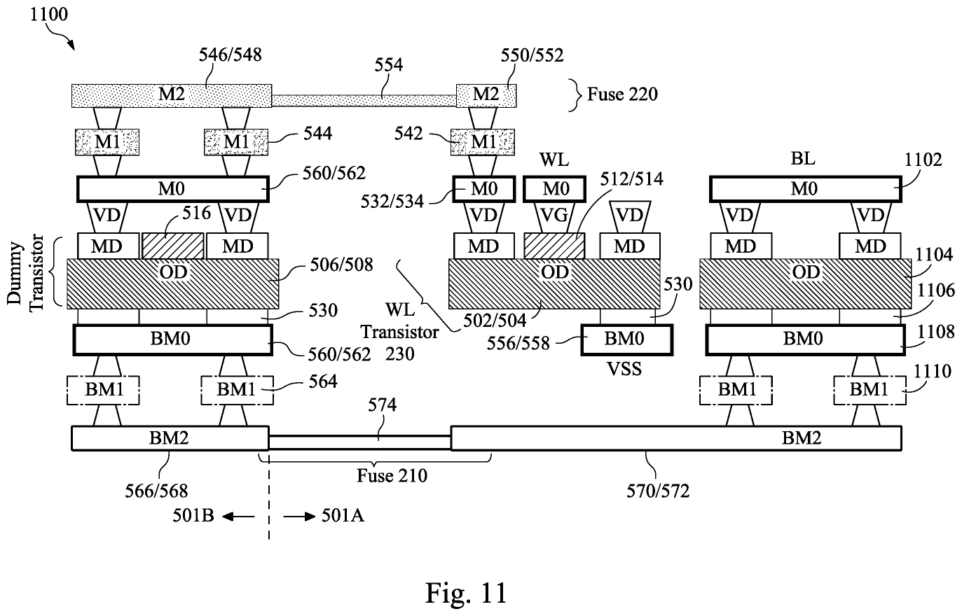

FIG. 11 illustrates a hybrid cross-sectional view of another semiconductor device 1100 that can be formed based on the layout 500 of FIG. 5, in accordance with some embodiments. The hybrid cross-sectional view of FIG. 11 may be a combination of some of the cross-sectional views of FIGS. 6-10, and may further include other components to align with the schematic diagram 200 of FIG. 2. In addition, relative arrangement among the components in the hybrid cross-sectional view of FIG. 11 may be adjusted from the layout 500 (FIG. 5) for illustrative purposes.

For example, the WL transistor 230 (FIG. 2) can be formed by the oxide diffusion regions 504-504 and the gate structures 512-514, the second fuse resistor 220 can be formed by the M2 tracks 546 to 554, and the first fuse resistor 210 can be formed by the BM2 tracks 566 to 574. The WL transistor 230 can have the gate terminal connected to a WL formed by at least one M0 track, one of the source/drain terminals connected to the M2 tracks 550/552 through at least the M0 tracks 532/534 and M1 track 542, and the other source/drain terminal connected to ground/VSS carried by the BM0 tracks 556-558. Specifically, the M2 tracks 546/548 (of the second fuse resistor 220) can be coupled to the BM2 tracks 566/568 of the first fuse resistor 210 through at least the M1 tracks 544, M0 tracks 560/562, BM0 tracks 560/562, and BM1 tracks 564.

As mentioned above, similar to the M2 tracks 546/548 of the second fuse resistor 220 on the frontside, the BM2 tracks 570/572 of the first fuse resistor 210 can extend away from its other terminal (BM2 tracks 566/568) to allow the first fuse resistor 210 to be couped to a BL, which may be formed by at least one M0 track 1102 in the area 501A. Accordingly, the BM2 tracks 570/572 may extend away from the area 501B. In some embodiments, the BL 1102 can be coupled to the BM2 tracks 570/572 through at least an oxide diffusion region 1104 (or epitaxial structures formed therein), one or more VBs 1106, one or more BM0 tracks 1108, and one or more BM1 tracks 1110, as illustrated in the example of FIG. 11. In some embodiments, the BL 1102 may be coupled to an input/output transistor (a part of the I/O circuit 108) that can generate a programming voltage and a reading voltage to be applied on the BL 1102.

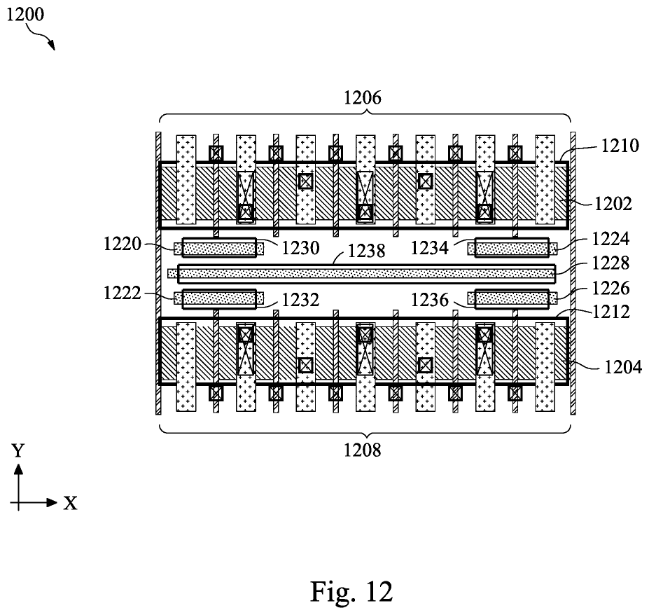

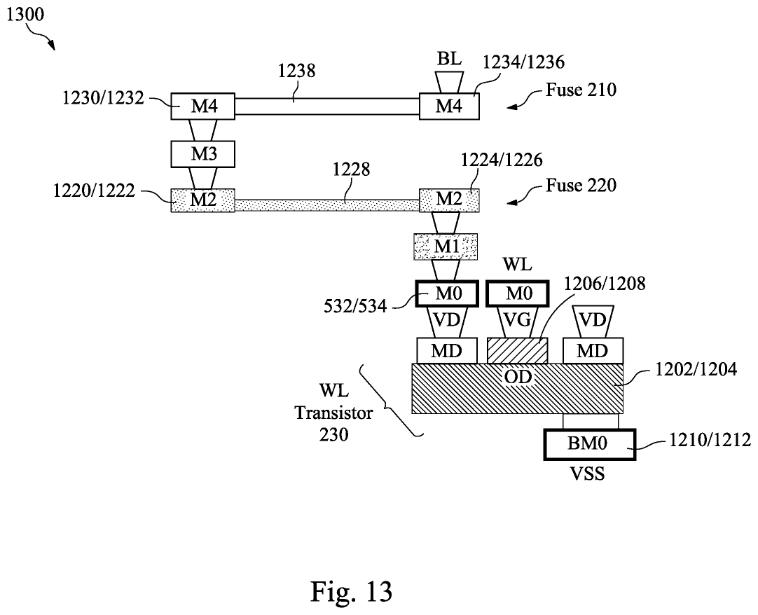

Referring next to FIG. 12, another example layout 1200 that can be utilized to form the efuse memory cell 200 (FIG. 2) is illustrated, in accordance with some embodiments. The layout 1200 is substantially similar to the layout 500 of FIG. 5, except that the layout 1200 is configured to form the first fuse resistor 210 on the frontside of a substrate (or the same side as the second fuse resistor 220). Accordingly, the following discussion of the layout 1200 will be focused on the difference. Further in FIG. 13, a hybrid cross-sectional view of a semiconductor device 1300 that can be formed by the layout 1200 is illustrated, in accordance with some embodiments. As such, the semiconductor device 1300 may be an implementation of the efuse memory cell 200. Relative arrangement among the components in the hybrid cross-sectional view of FIG. 13 may be adjusted from the layout 1200 (FIG. 12) for illustrative purposes.

As shown in FIG. 12, the layout 1200 includes patterns to form oxide diffusion regions 1202 and 1204, and gate structures 1206 and 1208 along the frontside surface of the substate, respectively. The oxide diffusion regions 1202-1204 and gate structures 1206-1208 can operatively serve as the WL transistor 230, as shown in FIG. 13. Referring again to FIG. 12, the layout 1200 further includes patterns to form a number of M2 tracks 1220, 1222, 1224, 1226, and 1228 over the frontside, respectively, and patterns to form a number of M4 tracks 1230, 1232, 1234, 1236, and 1238 over the frontside, respectively. In some embodiments, the M2 tracks 1220 to 1228 may be vertically aligned with the M4 tracks 1230 to 1238, respectively. The M2 tracks 1220-1226 can operatively serve as the fuse resistor 220, and the M4 tracks 1230-1236 can operatively serve as the fuse resistor 210, as shown in FIG. 13. One of the source/drain terminals of the WL transistor 230 is coupled to BM0 tracks 1210/1212 carrying ground/VSS, and the other source/drain terminal of the WL transistor 230 is coupled to a first terminal of the fuse resistor 220 (e.g., the M2 tracks 1224/1226). The fuse resistors 210 and 220 may have their second terminals (e.g., the M2 tracks 1220/1222 and the M4 tracks 1230/1232) coupled to each other through at least one M3 track. Further, a first terminal of the fuse resistor 210 (e.g., the M2 tracks 1234/1236) can be coupled to a BL, which may be formed by at least another metal track.

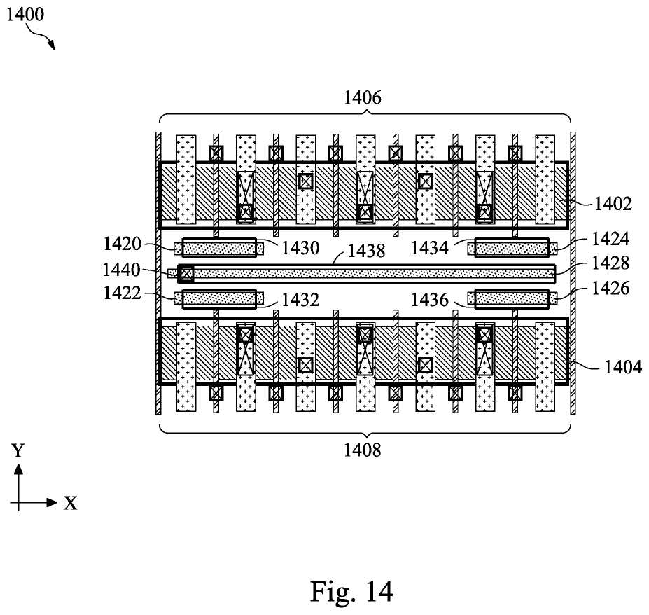

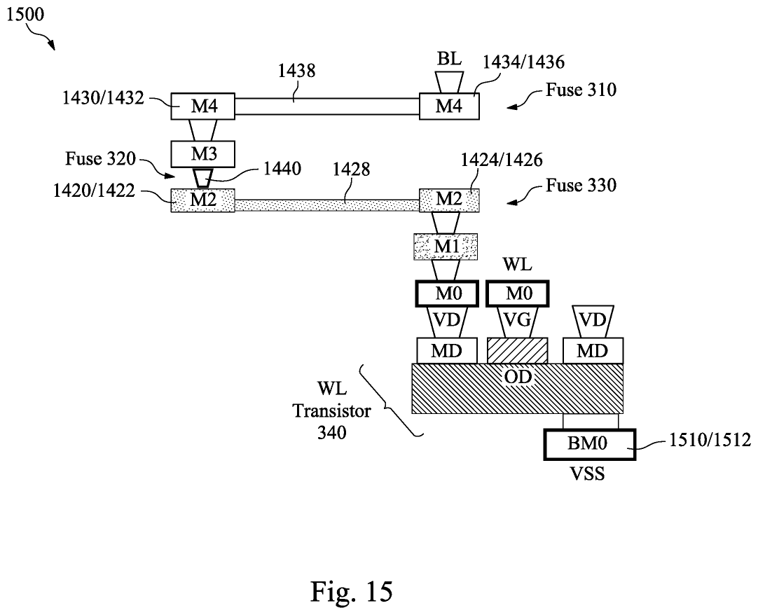

Referring next to FIG. 14, an example layout 1400 that can be utilized to form the efuse memory cell 300 (FIG. 3) is illustrated, in accordance with some embodiments. The layout 1400 is substantially similar to the layout 1200 of FIG. 12, except that the layout 1400 is configured to form an additional fuse resistor (e.g., 320) between two fuse resistors disposed on the frontside of a substrate (e.g., 310 and 330). Accordingly, the following discussion of the layout 1400 will be focused on the difference. Further in FIG. 15, a hybrid cross-sectional view of a semiconductor device 1500 that can be formed by the layout 1400 is illustrated, in accordance with some embodiments. As such, the semiconductor device 1500 may be an implementation of the efuse memory cell 300. Relative arrangement among the components in the hybrid cross-sectional view of FIG. 15 may be adjusted from the layout 1400 (FIG. 14) for illustrative purposes.

As shown in FIG. 14, the layout 1400 includes patterns to form oxide diffusion regions 1402 and 1404, and gate structures 1406 and 1408 along the frontside surface of the substate, respectively. The oxide diffusion regions 1402-1404 and gate structures 1406-1208 can operatively serve as the WL transistor 330, as shown in FIG. 15. Referring again to FIG. 14, the layout 1400 further includes patterns to form a number of M2 tracks 1420, 1422, 1424, 1426, and 1428 over the frontside, respectively, and patterns to form a number of M4 tracks 1430, 1432, 1434, 1436, and 1438 over the frontside, respectively. In some embodiments, the M2 tracks 1420 to 1428 may be vertically aligned with the M4 tracks 1430 to 1438, respectively. The M2 tracks 1420-1426 can operatively serve as the fuse resistor 330, and the M4 tracks 1430-1436 can operatively serve as the fuse resistor 310, as shown in FIG. 15. Further, the layout 1400 includes a pattern to form a via structure 1440 interposed between the M2 tracks and the M4 tracks (e.g., between the M2 track 1428 and the M4 track 1438). In some embodiments, such a via structure 1440 can operatively serve as the fuse resistor 320 coupled between the fuse resistors 310 and 330. One of the source/drain terminals of the WL transistor 340 is coupled to BM0 tracks 1510/1512 carrying ground/VSS, and the other source/drain terminal of the WL transistor 340 is coupled to a first terminal of the fuse resistor 330 (e.g., the M2 tracks 1424/1426). The fuse resistors 310 and 330 may have their second terminals (e.g., the M2 tracks 1420/1422 and the M4 tracks 1430/1432) coupled to each other through at least one M3 track and the via structure 1440. Further, a first terminal of the fuse resistor 310 (e.g., the M2 tracks 1434/1436) can be coupled to a BL, which may be formed by at least another metal track.

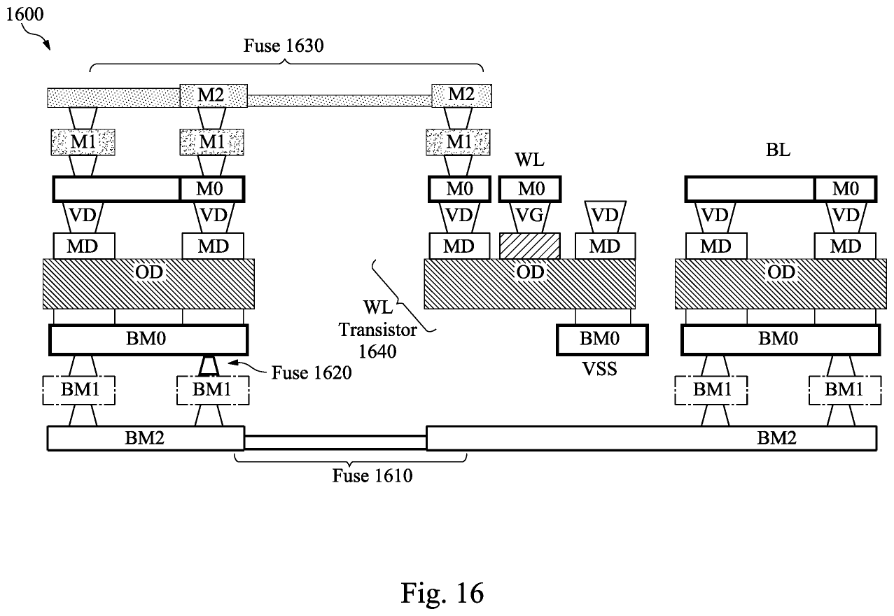

FIG. 16 illustrates a hybrid cross-sectional view of a semiconductor device 1600, in accordance with some embodiments. The semiconductor device 1600 is substantially similar to a combination of the semiconductor device 1100 (FIG. 11) and the semiconductor device 1500 (FIG. 15). The semiconductor device 1600 may be another implementation of the efuse memory cell 300 of FIG. 3. For example, the semiconductor device 1600 includes a WL transistor 1640 formed along the frontside of a substrate, a fuse resistor 1610 formed of a number of BM2 tracks, a fuse resistor 1630 formed of a number of M2 tracks, and a fuse resistor 1620 formed of a backside via structure, which can correspond to the WL transistor 340, fuse resistor 310, fuse resistor 330, and fuse resistor 320, respectively.

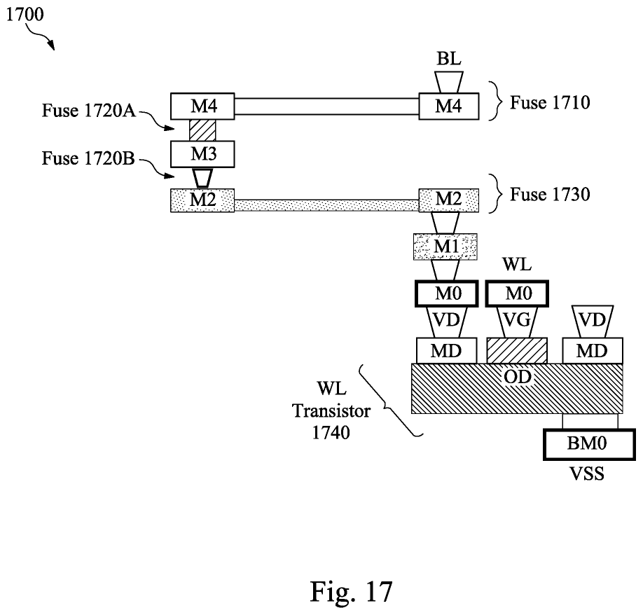

FIG. 17 illustrates a hybrid cross-sectional view of a semiconductor device 1700, in accordance with some embodiments. The semiconductor device 1700 is substantially similar to the semiconductor device 1500 (FIG. 15). The semiconductor device 1700 may be yet another implementation of the efuse memory cell 300 of FIG. 3, which includes an additional fuse resistor coupled between the fuse resistors 310 and 340. For example, the semiconductor device 1700 includes a WL transistor 1740 formed along the frontside of a substrate, a fuse resistor 1710 formed of a number of M4 tracks, a fuse resistor 1730 formed of a number of M2 tracks, and a fuse resistor 1720B formed of a backside via structure, which can correspond to the WL transistor 340, fuse resistor 310, fuse resistor 330, and fuse resistor 320, respectively. The semiconductor device 1700 may further include another fuse resistor 1720A that can be formed of an RRAM cell, an MRAM cell, or a PCRAM cell. Such an additional fuse resistor can be coupled between the fuse resistors 320 and 330 or between the fuse resistors 320 and 310 (FIG. 3).

In the example where the fuse resistor 1720A is implemented as an RRAM cell, the fuse resistor 1720A can include at least one variable resistance layer interposed between a top electrode and a bottom electrode, which, in the example of FIG. 17, may be implemented as an M4 track and an M3 track, respectively. In some embodiments, the variable resistance layer includes at least one of: nickel oxide (NiO), titanium oxide (TiO), hafnium oxide (HfO), zirconium oxide (ZrO), zinc oxide (ZnO), tungsten oxide (WO₃), aluminum oxide (Al₂O₃), tantalum oxide (TaO), molybdenum oxide (MoO), and copper oxide (CuO).

In the example where the fuse resistor 1720A is implemented as a PCRAM cell, the fuse resistor 1720A can include at least one phase change material layer and a heater interposed between a top electrode and a bottom electrode, which, in the example of FIG. 17, may be implemented as an M4 track and an M3 track, respectively. In some embodiments, the phase change material layer includes one of: a binary system of Ga—Sb, In—Sb, In—Se, Sb—Te, Ge—Te, and Ge—Sb; a ternary system, of Ge—Sb—Te, In—Sb—Te, Ga—Se—Te, Sn—Sb—Te, In—Sb—Ge, and Ga—Sb—Te; or a quaternary system of Ag—In—Sb—Te, Ge—Sn—Sb—Te, Ge—Sb—Se—Te, Te—Ge—Sb—S, Ge—Sb—Te—O, and Ge—Sb—Te—N. In some embodiments, the phase change material layer includes a chalcogenide alloy containing one or more elements from Group VI of the periodic table, such as a GST, a Ge—Sb—Te alloy (e.g. Ge₂Sb₂Te₅). The heater, formed of a metal material, may function as a heat sink during quenching of the phase change material layer (during the abrupt cutoff of a current applied to the heater to freeze an amorphous phase).

In the example where the fuse resistor 1720A is implemented as an MRAM cell, the fuse resistor 1720A can include at least a ferromagnetic free layer, a dielectric spacer functioning as a tunneling barrier, a ferromagnetic pinned layer, and an antiferromagnetic pinning layer arranged in such an order between a top electrode and a bottom electrode, which, in the example of FIG. 17, may be implemented as an M4 track and an M3 track, respectively. In some embodiments, the ferromagnetic free layer and the ferromagnetic pinned layer are constructed of ferromagnetic material, for example cobalt-iron or nickel-cobalt-iron. The antiferromagnetic pinning layer is constructed of antiferromagnetic material, for example platinum manganese. Magnetostatic coupling between the ferromagnetic pinned layer and the antiferromagnetic pinning layer causes the ferromagnetic pinned layer to have a fixed magnetic moment. The ferromagnetic free layer, on the other hand, has a magnetic moment that, by application of a magnetic field, can be switched between a first orientation, which is parallel to the magnetic moment of the ferromagnetic pinned layer, and a second orientation, which is antiparallel to the magnetic moment of the ferromagnetic pinned layer.

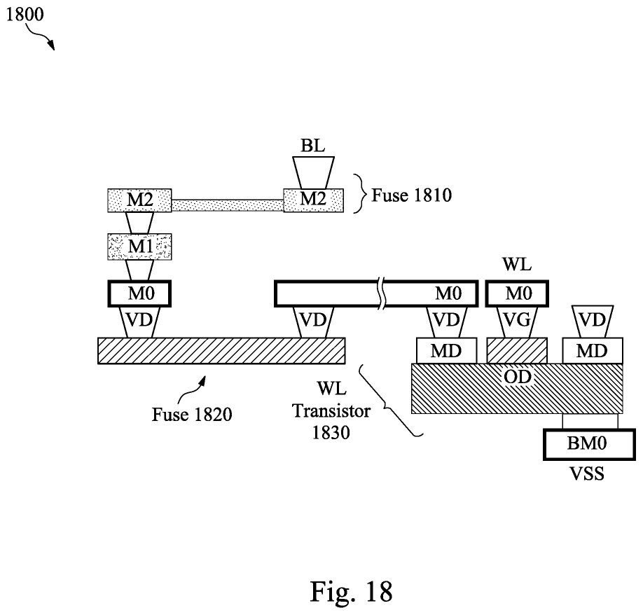

FIG. 18 illustrates a hybrid cross-sectional view of a semiconductor device 1800, in accordance with some embodiments. The semiconductor device 1800 may be yet another implementation of the efuse memory cell 200 of FIG. 2. The semiconductor device 1800 is substantially similar to the semiconductor device 1300 (FIG. 13), except that one of the fuse resistors may also be formed along the frontside surface of a substrate. For example, the semiconductor device 1800 includes a WL transistor 1830 formed along the frontside of the substrate, a fuse resistor 1810 formed of a number of M2 tracks, and a fuse resistor 1820 formed of a gate structure. The fuse resistor 1820 may include a polysilicon material or metal material. In some embodiments, the fuse resistor 1820 may be formed to arrange in parallel with a gate terminal of the WL transistor 1830. Further, in some embodiments, the fuse resistor 1820 may have a width substantially narrower than a width of the gate terminal of the WL transistor 1830.

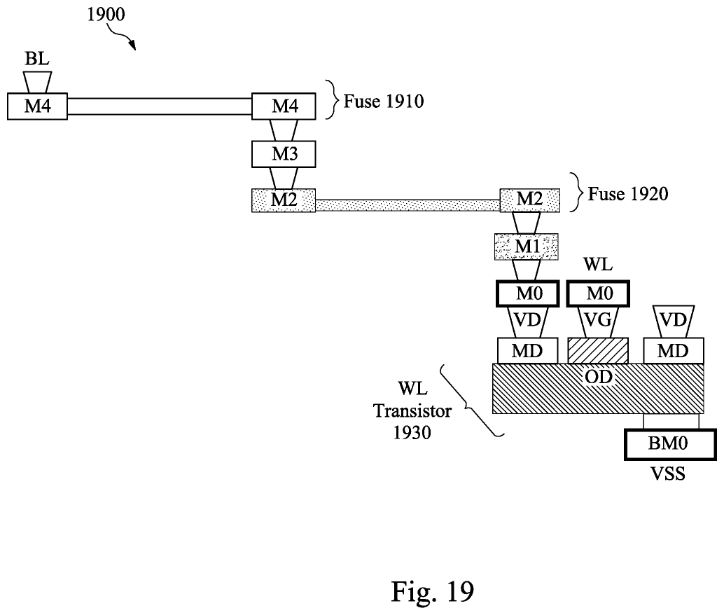

FIG. 19 illustrates a hybrid cross-sectional view of a semiconductor device 1900, in accordance with some embodiments. The semiconductor device 1900 may be yet another implementation of the efuse memory cell 200 of FIG. 2. The semiconductor device 1900 is substantially similar to the semiconductor device 1300 (FIG. 13), except that respective metal tracks of the fuse resistors are not vertically aligned. For example, the semiconductor device 1900 includes a WL transistor 1930 formed along the frontside of a substrate, a fuse resistor 1910 formed of a number of M4 tracks, and a fuse resistor 1920 formed of a number of M2 tracks. In some embodiments, except for the metal tracks that connecting the fuse resistor 1920 to the fuse resistor 1910, the metal tracks of the fuse resistor 1910 and the metal tracks of the fuse resistor 1920 may not be vertically aligned.

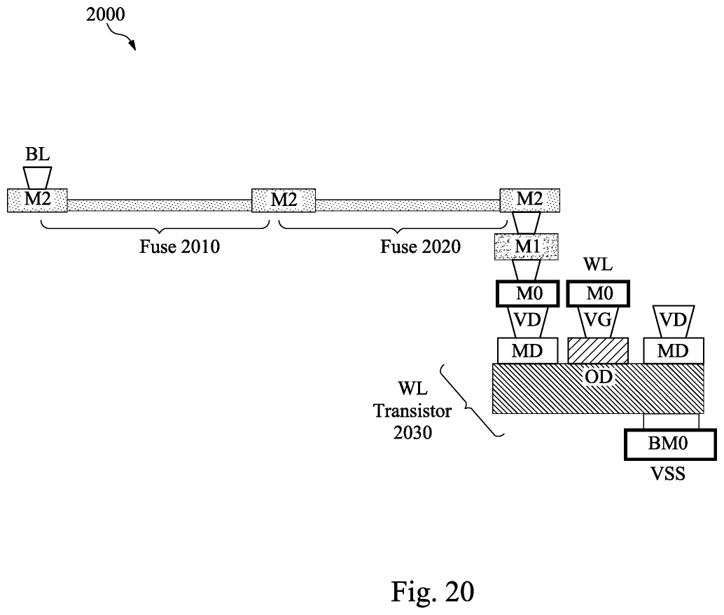

FIG. 20 illustrates a hybrid cross-sectional view of a semiconductor device 2000, in accordance with some embodiments. The semiconductor device 2000 may be yet another implementation of the efuse memory cell 200 of FIG. 2. The semiconductor device 2000 is substantially similar to the semiconductor device 1300 (FIG. 13), except that respective metal tracks of the fuse resistors are disposed in a same metallization layer. For example, the semiconductor device 2000 includes a WL transistor 2030 formed along the frontside of a substrate, a fuse resistor 2010 formed of a number of M2 tracks, and a fuse resistor 2020 formed of a number of other M2 tracks. In some embodiments, except for the metal tracks that connecting the fuse resistor 2020 to the fuse resistor 2010, the metal tracks of the fuse resistor 2010 and the metal tracks of the fuse resistor 2020 may be laterally spaced from one another.

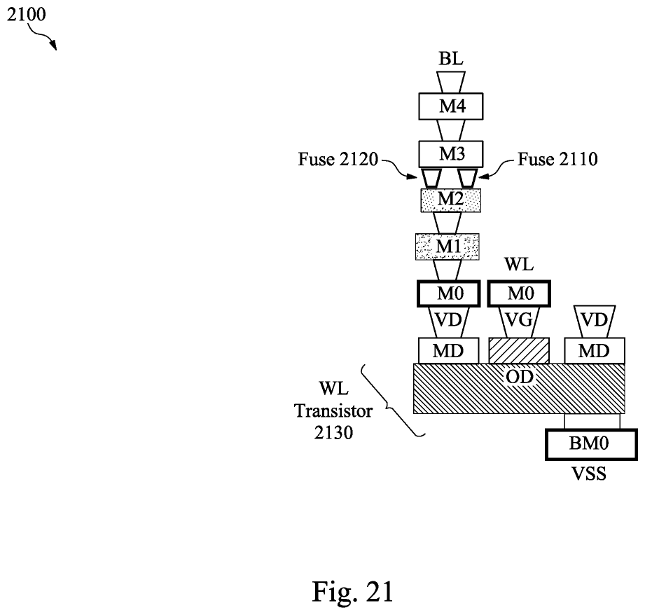

FIG. 21 illustrates a hybrid cross-sectional view of a semiconductor device 2100, in accordance with some embodiments. The semiconductor device 2100 may be an implementation of the efuse memory cell 400 of FIG. 4. For example, the semiconductor device 2100 includes a WL transistor 2130 formed along the frontside of a substrate, a fuse resistor 2110, and a fuse resistor 2120, in which the fuse resistors 2110 and 2120 are coupled to each other in parallel, while each being connected to the WL transistor 2130 in series. In the illustrative example of FIG. 21, the fuse resistor 2110 may be formed of a via structure interposed between an M2 track and an M3 track, and the fuse resistor 2120 may be formed of another via structure interposed between the same M2 and M3 tracks.

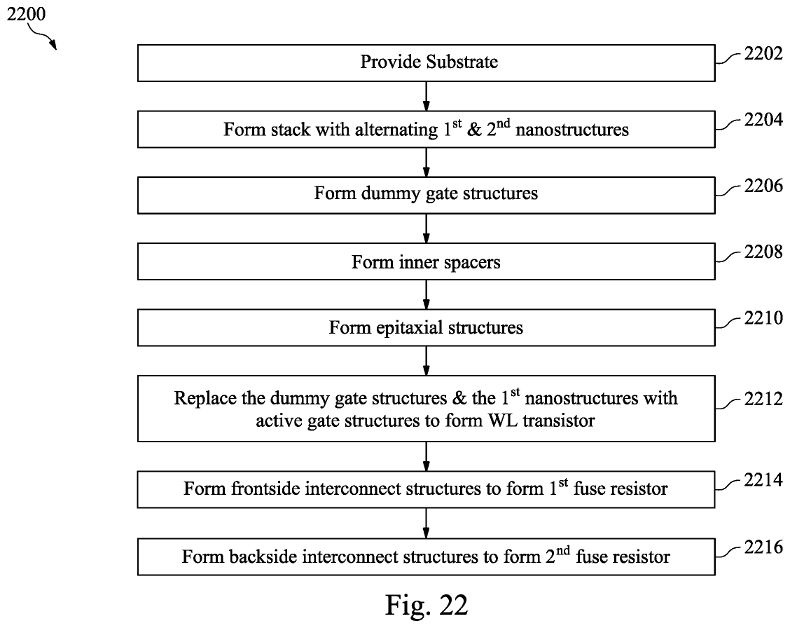

FIG. 22 illustrates a flow chart of an example method 2200 for forming an efuse memory cell including a plural number of fuse resistors, in accordance with some embodiments. The efuse memory cell, made by the method 2200, can include a first fuse resistor formed on the frontside of a substrate and a second fuse resistor formed on a backside of the substrate. In some embodiments, the method 2200 can be performed to form an efuse memory cell (e.g., 200 of FIG. 2) based on the layout 500 shown in FIG. 5, and thus, some of the references used above may be reused in the following discussion of the method 2200. It is noted that the method 2200 is merely an example and is not intended to limit the present disclosure. Accordingly, it is understood that additional operations may be provided before, during, and after the method 2200 of FIG. 22, and that some other operations may only be briefly described herein.

The method 2200 starts with operation 2202 in which a substrate is provided, in accordance with various embodiments. The substrate includes a semiconductor material substrate, for example, silicon. Alternatively, the substrate may include other elementary semiconductor material such as, for example, germanium. The substrate may also include a compound semiconductor such as silicon carbide, gallium arsenic, indium arsenide, and indium phosphide. The substrate may include an alloy semiconductor such as silicon germanium, silicon germanium carbide, gallium arsenic phosphide, and gallium indium phosphide. In one embodiment, the substrate includes an epitaxial layer. For example, the substrate may have an epitaxial layer overlying a bulk semiconductor. Furthermore, the substrate may include a semiconductor-on-insulator (SOI) structure. For example, the substrate may include a buried oxide (BOX) layer formed by a process such as separation by implanted oxygen (SIMOX) or other suitable technique, such as wafer bonding and grinding.

The method 2200 continues to operation 2204 in which a stack, including an alternating series of first nanostructures and second nanostructures, is formed, in accordance with various embodiments. Such a stack can be formed based on one of the (oxide diffusion) patterns discussed above. The stack can be formed in a frontside of the substrate. In some embodiments, the first nanostructures may include SiGe sacrificial nanostructures, and the second nanostructures may include Si channel nanostructures. Such a stack may sometimes be referred to as a superlattice. In a non-limiting example, the SiGe sacrificial nanostructures can be SiGe 25%. The notation “SiGe 25%” is used to indicate that 25% of the SiGe material is Ge. It is understood the percentage of Ge in each of the SiGe sacrificial nanostructures can be any value between 0 and 100 (excluding 0 and 100), while remaining within the scope of present disclosure. In some other embodiments, the second nanostructures may include a first semiconductor material other than Si and the first nanostructures may include a second semiconductor material other than SiGe, as long as the first and second semiconductor materials are respectively characterized with different etching properties (e.g., etching rates).

The alternating series of nanostructures can be formed by epitaxially growing one layer and then the next until the desired number and desired thicknesses of the nanostructures are achieved. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) silicon can be doped during deposition (in-situ doped) by adding dopants, n-type dopants (e.g., phosphorus or arsenic) or p-type dopants (e.g., boron or gallium), depending on the type of transistor.

The method 2200 continues to operation 2206 in which a number of dummy gate structures are formed, in accordance with various embodiments. Such a dummy gate structure can be formed based on one of the (gate structure) patterns discussed above. The dummy gate structure can extend along a direction perpendicular to the lengthwise direction of the dielectric fin structure (and the stack). Further, the dummy gate structure may be formed shorter than the dielectric fin structure in one of various embodiments, and thus, the dummy gate structure, as formed, is cut (or otherwise separated) by the dielectric fin structure.

The dummy gate structure can be formed by depositing amorphous silicon (a-Si) over the stack. Other materials suitable for forming dummy gates (e.g., polysilicon) can be used while remaining within the scope of present disclosure. The a-Si is then planarized to a desired level. A hard mask is deposited over the planarized a-Si and patterned. The hard mask can be formed from a nitride or an oxide layer. An etching process (e.g., a reactive-ion etching (RIE) process) is applied to the a-Si to form the dummy gate structure. After forming the dummy gate structure, gate spacers may be formed to extend along sidewalls of the dummy gate structure. The gate spacers can be formed by a conformal deposition of a dielectric material (e.g., silicon oxide, silicon nitride, silicon oxynitride, SiBCN, SiOCN, SiOC, or any suitable combination of those materials) followed by a directional etch (e.g., RIE).

The method 2200 proceeds to operation 2208 in which inner spacers are formed by replacing end portions of each of the SiGe sacrificial nanostructures with a dielectric material, in accordance with various embodiments. Upon forming the dummy gate structure overlaying certain portions of the stack (e.g., the portions of the stack separated by the dielectric fin structure), the non-overlaid portions of the stack are removed. Next, respective end portions of each SiGe sacrificial nanostructure of the overlaid stack are removed. The inner spacers are formed by filling such recesses of each SiGe sacrificial nanostructure with a dielectric material by chemical vapor deposition (CVD), or by monolayer doping (MLD) of nitride followed by spacer RIE. A material of the inner spacers can be formed from the same or different material as the gate spacers described above. For example, the inner spacers can be formed of silicon nitride, silicoboron carbonitride, silicon carbonitride, silicon carbon oxynitride, or any other type of dielectric material (e.g., a dielectric material having a dielectric constant k of less than about 5).

The method 2200 proceeds to operation 2210 in which a number of epitaxial structures are formed, in accordance with various embodiments. Upon forming the inner spacers, the epitaxial structures are formed using an epitaxial layer growth process on exposed ends of the Si nanostructures. In-situ doping (ISD) may be applied to form doped epitaxial structures, thereby creating the necessary junctions for a corresponding transistor (or sub-transistor). N-type and p-type FETs are formed by implanting different types of dopants to selected regions of the device to form the necessary junction(s). N-type devices can be formed by implanting arsenic (As) or phosphorous (P), and p-type devices can be formed by implanting boron (B). After forming the epitaxial structures, an inter-layer dielectric (e.g., silicon dioxide) is deposited to overlay the epitaxial structures.

The method 2200 proceeds to operation 2212 in which the dummy gate structures and the remaining SiGe sacrificial nanostructures are replaced with respective active gate structures, in accordance with various embodiments. Subsequently to forming the inter-layer dielectric, the dummy gate structures are removed by an etching process, e.g., RIE or chemical oxide removal (COR). Next, the remaining SiGe sacrificial nanostructures are removed while keeping the Si channel nanostructure substantially intact by applying a selective etch (e.g., a hydrochloric acid (HCl)). After the removal of the SiGe sacrificial nanostructures, top and bottom surfaces and sidewalls of each of the Si channel nanostructures can be exposed, except for the sidewall in contact with the dielectric fin structure. Next, a number of active gate structures can be formed to wrap around each of the Si channel nanostructures, except for the sidewall contacting the dielectric fin structure. Each of the active gate structures includes at least a gate dielectric layer (e.g., a high-k dielectric layer) and a gate metal layer (e.g., a work function metal layer). Upon the active gate structures being formed, the WL transistor 230 (FIG. 2) can be formed.

The method 2200 proceeds to operation 2214 in which a number of frontside interconnect structures are formed, in accordance with various embodiments. Upon forming the WL transistor (or its sub-transistors), a number of middle-end interconnect structures (e.g., VGs, VDs, MDs) are formed thereupon. For example, a number of VGs can be formed to be connected to gate terminals, respectively, and a number of MDs can be formed to be connected to source/drain terminals through a number of VDs, respectively. Further, a number of back-end interconnect structures can be formed over the middle-end interconnect structures. Such back-end interconnect structures include the above-described M0 tracks (e.g., 532-538), M1 tracks (e.g., 540-544), M2 tracks (e.g., 546-554), etc. In some embodiments, a number of the M2 tracks can operatively serve as the fuse resistor 220 (FIG. 2). In some embodiments, one terminal of the fuse resistor 220 is coupled to one source/drain terminal of the WL transistor 230 through a number of the middle-end and back-end interconnect structures disposed on the frontside.

The frontside interconnect structure is formed of a metal material. The metal material can be selected from the group consisting of aluminum, tungsten, tungsten nitride, copper, cobalt, silver, gold, chrome, ruthenium, platinum, titanium, titanium nitride, tantalum, tantalum nitride, nickel, hafnium, and combinations thereof. Other metal materials are within the scope of the present disclosure. The frontside interconnect structures can be formed by overlaying the frontside of the substrate with the above-listed metal material by, for example, chemical vapor deposition (CVD), physical vapor deposition (PVD), electroless plating, electroplating, or combinations thereof.

The method 2200 proceeds to operation 2216 in which a number of backside interconnect structures are formed, in accordance with various embodiments. Upon forming the back-end metal tracks, the substrate is flipped, and a number of backside interconnect structures (e.g., BM0 tracks, BM1 tracks, BM2 tracks, etc.) are formed over the backside of the substrate. For example, after the substrate is flipped, a polishing process may be performed on the backside of the substrate until a bottom surface of the epitaxial structures (e.g., the source/drain terminals formed in operation 2210) is exposed. Next, one or more dielectric layers are formed over the polished backside surface, followed by forming the above-described backside via structures (e.g., VBs 530) that can each extend through the one or more dielectric layers to reach the bottom surface of a corresponding epitaxial structure. Next, the backside interconnect structures (e.g., 556-562, 564, 566-574, etc.) can be formed in respective backside metallization layers. In some embodiments, a number of the BM2 tracks can operatively serve as the fuse resistor 210 (FIG. 2). In some embodiments, one terminal of the fuse resistor 210 is coupled to the other terminal of the fuse resistor 220 through a number of the middle-end and back-end interconnect structures disposed on the frontside and further through a number of backside interconnect structures. In some embodiments, such interconnect structures coupling the fuse resistor 210 to the fuse resistor 220 may be disposed in an area (e.g., 501B) laterally around an area (e.g., 501A) where the WL transistor 230 is formed.

The backside interconnect structure is formed of a metal material. The metal material can be selected from the group consisting of aluminum, tungsten, tungsten nitride, copper, cobalt, silver, gold, chrome, ruthenium, platinum, titanium, titanium nitride, tantalum, tantalum nitride, nickel, hafnium, and combinations thereof. Other metal materials are within the scope of the present disclosure. The backside interconnect structures can be formed by overlaying the backside of the substrate with the above-listed metal material by, for example, chemical vapor deposition (CVD), physical vapor deposition (PVD), electroless plating, electroplating, or combinations thereof.

In one aspect of the present disclosure, a memory device is disclosed. The memory device includes a transistor formed along a frontside surface of a substrate. The memory device includes a first fuse resistor formed in a first metallization layer that is vertically disposed with respect to the frontside surface. The memory device includes a second fuse resistor formed in a second metallization layer that is vertically disposed with respect to the frontside surface, the first metallization layer being different from the second metallization layer. The second fuse resistor and the first fuse resistor are each coupled to the transistor.

In another aspect of the present disclosure, a memory device is disclosed. The memory device includes a one-time-programmable (OTP) memory cell comprising a transistor, a first resistor, and a second resistor. The second resistor is coupled to the first resistor in series, and the first resistor is coupled to the transistor in series. The first resistor, the second resistor, and the transistor are vertically spaced from one another.

In yet another aspect of the present disclosure, a method is disclosed. The method includes forming a transistor along a frontside surface of a substrate. The method includes forming a plurality of frontside metal tracks disposed over the frontside surface, wherein the plurality of frontside metal tracks include a word line, a bit line, and a first fuse resistor. The method includes forming a plurality of backside metal tracks disposed over a backside surface of the substrate, wherein the plurality of backside metal tracks include a second fuse resistor. The word line is electrically connected to a gate terminal of the transistor, the bit line is electrically connected to a first end of the second fuse resistor, a second end of the second fuse resistor is electrically connected to a first end of the first fuse resistor, and a second end of the first fuse resistor is electrically connected to a source/drain terminal of the transistor.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory device, comprising:
a transistor formed along a frontside surface of a substrate;
a first fuse resistor formed in a first metallization layer that is vertically disposed with respect to the frontside surface; and
a second fuse resistor formed in a second metallization layer that is vertically disposed with respect to the frontside surface, the first metallization layer being different from the second metallization layer;
wherein the second fuse resistor and the first fuse resistor are each coupled to the transistor.

2. The memory device of claim 1, wherein the second fuse resistor, the first fuse resistor, and the transistor are coupled to each other in series.

3. The memory device of claim 1, wherein the second fuse resistor and the first fuse resistor are coupled to each other in parallel, and each of the second fuse resistor and the first fuse resistor is coupled to the transistor in series.

4. The memory device of claim 1, wherein one of the first fuse resistor or the second fuse resistor is configured to be randomly blown, thereby permanently presenting a logic state.

5. The memory device of claim 1, wherein
the first fuse resistor includes a first metal track, a second metal track, a third metal track, a fourth metal track, and a fifth metal track, the first to fifth metal tracks disposed in the first metallization layer and extending along a first lateral direction;
the second fuse resistor includes a sixth metal track, a seventh metal track, an eighth metal track, a ninth metal track, and a tenth metal track, the sixth to tenth metal tracks disposed in the second metallization layer and extending along the first lateral direction.

6. The memory device of claim 5, wherein the first metal track has a first end and a second end along the first lateral direction, wherein the first end of the first metal track is interposed between the second metal track and the third metal track along a second lateral direction perpendicular to the first lateral direction, and wherein the second end of the first metal track is interposed between the fourth metal track and the fifth metal track along the second lateral direction.

7. The memory device of claim 6, wherein the sixth metal track has a first end and a second end along the first lateral direction, wherein the first end of the sixth metal track is interposed between the seventh metal track and the eighth metal track along the second lateral direction, and wherein the second end of the sixth metal track is interposed between the ninth metal track and the tenth metal track along the second lateral direction.

8. The memory device of claim 7, wherein the second metal track and the third metal track each have a first portion extending away from the first end of the first metal track along the first lateral direction, and wherein the seventh metal track and the eighth metal track each have a second portion extending away from the first end of the sixth metal track along the first lateral direction.

9. The memory device of claim 8, wherein the first portion and the second portion are coupled to each other through at least a plurality of via structures.

10. The memory device of claim 9, wherein each of the plurality of via structures extends through a backside surface of the substrate opposite to the frontside surface.

11. The memory device of claim 8, wherein the first portion and the second portion are disposed in a first area of the substrate spaced away from a second area of the substrate, and wherein at least the transistor is formed in the second area.

12. A memory device, comprising:
a one-time-programmable (OTP) memory cell comprising a transistor, a first resistor, and a second resistor;
wherein the second resistor is coupled to the first resistor in series, and the first resistor is coupled to the transistor in series;
wherein the first resistor, the second resistor, and the transistor are vertically spaced from one another.

13. The memory device of claim 12, wherein one of the first resistor or the second resistor is configured to be randomly blown, causing the OTP memory cell to permanently present a logic state.

14. The memory device of claim 12, wherein the transistor is formed along a frontside surface of a substrate, the first resistor comprising a plurality of first metal tracks that are formed in one of a plurality of frontside metallization layers disposed over the frontside surface, and the second resistor comprising a plurality of second metal tracks that are formed in one of a plurality of backside metallization layers disposed over a backside surface of the substrate.

15. The memory device of claim 12, wherein the transistor is formed along a frontside surface of a substrate, the first resistor comprising a plurality of first metal tracks that are formed in a first one of a plurality of frontside metallization layers disposed over the frontside surface, and the second resistor comprising a plurality of second metal tracks that are formed in a second one of the plurality of frontside metallization layers.

16. The memory device of claim 12, wherein the OTP memory cell further comprises a third resistor, the third resistor coupled between the first resistor and the second resistor in series.

17. The memory device of claim 16, wherein the transistor is formed along a frontside surface of a substrate, the first resistor comprising a plurality of first metal tracks that are formed in a first one of a plurality of frontside metallization layers disposed over the frontside surface, the second resistor comprising a plurality of second metal tracks that are formed in a second one of the plurality of frontside metallization layers, and the third resistor comprising a via structure interposed between the first frontside metallization layer and the second frontside metallization layer.

18. The memory device of claim 16, wherein the transistor is formed along a frontside surface of a substrate, the first resistor comprising a plurality of first metal tracks that are formed in one of a plurality of frontside metallization layers disposed over the frontside surface, the second resistor comprising a plurality of second metal tracks that are formed in one of a plurality of backside metallization layers disposed over a backside surface of the substrate, and the third resistor comprising a via structure interposed between the backside surface and the backside metallization layer.

19. A method, comprising:
forming a transistor along a frontside surface of a substrate;
forming a plurality of frontside metal tracks disposed over the frontside surface, wherein the plurality of frontside metal tracks include a word line, a bit line, and a first fuse resistor; and
forming a plurality of backside metal tracks disposed over a backside surface of the substrate, wherein the plurality of backside metal tracks include a second fuse resistor;
wherein the word line is electrically connected to a gate terminal of the transistor, the bit line is electrically connected to a first end of the second fuse resistor, a second end of the second fuse resistor is electrically connected to a first end of the first fuse resistor, and a second end of the first fuse resistor is electrically connected to a source/drain terminal of the transistor.

20. The method of claim 19, wherein the first fuse resistor and the second fuse resistor are vertically aligned with each other.
